(19) United States
(12) Patent Application Publication
(10) Pub. No.: US 2007/0285291 A1
(43) Pub. Date: Dec. 13, 2007

(54) Binarization circuit

(75) Inventors: Yasuaki Makino, Okazaki-city (JP); Susumu Kuroyanagi, Anjo-city (JP); Shinji Nakatani, Okazaki-city (JP); Reiji Iwamoto, Nukata-gun (JP); Hideki Hosokawa, Owariasahi-city (JP); Norikazu Ohta, Aichi-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/717,169

(22) Filed: Mar. 13, 2007

(30) Foreign Application Priority Data
Mar. 15, 2006 (JP) 2006-70147
Dec. 20, 2006 (JP) 2006-342794

(51) Int. Cl. H03M 1/12

(52) U.S. Cl. 341/132; 341/126

(57) ABSTRACT

A binarization circuit for binarizing a pulsative analog signal includes: a first comparator circuit for reversing an output signal when the analog signal becomes smaller than a threshold voltage and when the analog signal becomes larger than a high side threshold voltage; a second comparator circuit for reversing an output signal when the analog signal becomes larger than the threshold voltage and when the analog signal becomes smaller than a low side threshold voltage; and a selector circuit for inputting the output signals from the first and second comparator circuits and for reversing an output signal when the analog signal becomes smaller than the threshold voltage and when the analog signal becomes larger than the threshold voltage.

### CROSS REFERENCE TO RELATED APPLICATIONS

This application is based on Japanese Patent Applications No. 2006-70147 filed on Mar. 15, 2006, and No. 2006-342794 filed on Dec. 20, 2006, the disclosures of which are incorporated herein by reference.

### FIELD OF THE INVENTION

The present invention relates to a binarization circuit.

### BACKGROUND OF THE INVENTION

A binarization circuit outputs a binarization signal Vo. For example, as shown in FIG. 1A, a pulsative analog signal Vi is compared with a threshold voltage Vref. As shown in FIG. 1B, when the analog signal Vi becomes larger than the threshold voltage Vref at a time t1, t3, the binarization signal Vo switches from a low state to a high state. When the analog signal Vi becomes smaller than the threshold voltage Vref at a time t2, t4, the binarization signal Vo switches from the high state to the low state.

Here, the analog signal Vi is inputted in one input terminal of a comparator, and the threshold voltage Vref is inputted in the other input terminal of the comparator. The output voltage from the comparator flips when the analog signal Vi becomes larger than the threshold voltage Vref, and flips again when the analog signal becomes smaller than the threshold voltage Vref. Thus, the comparator outputs the binarization signal Vo. By using the binarization signal Vo, the number of flips can be counted, so that a frequency or the like in the analog signal Vi is measured.

In some cases, a high frequency component may be overlapped on the analog signal Vi. FIG. 1C shows the analog signal Vi, which increases with time and has the high frequency component overlapped thereon.

When the analog signal Vi with the high frequency component is inputted in the comparator, the output voltage of the comparator repeats to flip and flip again attributed to the high frequency component, as shown in FIG. 1D. Accordingly, when the high frequency component is overlapped on the analog signal Vi, the output voltage of the comparator may chatter, as shown in FIG. 1E. When the binarization signal Vo chatters, it is difficult to count the number of flips for measuring the frequency or the like of the analog signal Vi.

Thus, a comparator circuit having a hysteresis characteristic is proposed.

This circuit is disclosed in, for example, “Sensors for Automotive Technology” in Sensors Applications Vol. 4, Wiley-Ach GmbH & Co., Pages 423-424.

The comparator circuit temporally switches between a high side offset threshold voltage Vref1 and a low side offset threshold voltage Vref2, as shown in FIG, 2A. The high side offset threshold voltage Vref1 is set to be higher than the threshold Vref, and the low side offset threshold voltage Vref2 is set to be lower than the threshold Vref. In general, the threshold voltage Vref is set to be the average voltage Vav of the analog signal Vi.

The comparator circuit switches a comparison reference voltage from the high side offset threshold voltage Vref1 to the low side offset threshold voltage Vref2 when the analog signal Vi becomes larger than the high side offset threshold voltage Vref1 at the time t1, t3. The comparator circuit switches the comparison reference voltage from the low side offset threshold voltage Vref2 to the high side offset threshold voltage Vref1 when the analog signal Vi becomes smaller than the low side offset threshold voltage Vref2 at the time t2, t4.

By using the comparator circuit, the output voltage of the comparator circuit is prevented from chattering even when the high frequency corn ponent is overlapped on the analog signal Vi, as shown in FIG. 2C. Further, as shown in FIG. 2B, when the analog signal Vi becomes larger than the high side offset threshold voltage Vref1, the binarization signal Vo flips. Further, when the analog signal Vi becomes smaller than the low side offset threshold voltage Vref2, the binarization signal Vo flips again.

Thus, the output voltage of the comparator circuit is prevented from chattering. However, as shown in FIG. 2B, the timing t1-t4 of switching the binarization signal Vo is deviated by a predetermined time ΔT from a timing T1-T4, at which the analog signal Vi becomes larger or smaller than the threshold voltage Vref.

Thus, it is required for a binarization circuit to output a binarization signal without chattering even when a high frequency component is overlapped on an analog signal. Further, it is required for the binarization circuit to switch the binarization signal at a timing when the analog signal changes across a threshold voltage.

### SUMMARY OF THE INVENTION

In view of the above-described problem, it is an object of the present disclosure to provide a binarization circuit.

According to an aspect of the present disclosure, a binarization circuit for binarizing a pulsative analog signal includes: a first comparator circuit for reversing an output signal thereof when the analog signal becomes smaller than a predetermined threshold voltage and when the analog signal becomes larger than a high side threshold voltage, wherein the high side threshold voltage is higher than the threshold voltage; a second comparator circuit for reversing an output signal thereof when the analog signal becomes larger than the threshold voltage and when the analog signal becomes smaller than a low side threshold voltage, wherein the low side threshold voltage is lower than the threshold voltage; and a selector circuit for inputting the output signals from the first and second comparator circuits and for reversing an output signal of the selector circuit. The output signal of the selector circuit is reversed when the first comparator circuit reverses the output signal of the first comparator circuit in a case where the analog signal becomes smaller than the threshold voltage and when the second comparator circuit reverses the output signal of the second comparator circuit in a case where the analog signal becomes larger than the threshold voltage.

In the above circuit, since each of the first and second comparator circuits has a hysteresis characteristic, the output of the circuit does not chatter when the analog signal becomes smaller than the threshold voltage and when the analog signal becomes larger than the threshold voltage. Further, the binarization signal is reversed when the analog signal becomes smaller than the threshold voltage and when the analog signal becomes larger than the threshold voltage.

### BRIEF DESCRIPTION OF THE DRAWINGS

The above and other objects, features and advantages of the present invention will become more apparent from the following detailed description made with reference to the accompanying drawings. In the drawings:

FIG. 1A is a graph showing an analog signal, FIG. 1B is a graph showing a binarization signal obtained from the analog signal in FIG. 1A, FIG. 1C is a graph showing another analog signal increasing with time, FIG. 1D is a graph showing a part of another binarization signal obtained from the analog signal in FIG. 1C, and FIG. 1E is a graph showing the another binarization signal, according to a related art;

FIG. 2A is a graph showing an analog signal, FIG. 2B is a graph showing a binarization signal obtained from the analog signal in FIG. 2A, and FIG. 2C is a graph showing a method for binarizing an analog signal, according to a prior art;

FIG. 3A is a circuit diagram showing a binarization circuit according to a first embodiment, FIGS. 3B and 3C are graphs showing an analog signal and comparison reference voltages, and FIGS. 3D and 3E are graphs showing binarization signals obtained from the analog signal in FIGS. 3B and 3C;

FIG. 4A is a graph showing an analog signal and comparison reference voltages, FIGS. 4B and 4C are graphs showing output voltages from comparator circuits, FIG. 4D is a graph showing a binarization signal obtained from the analog signal in FIG. 4A, FIG. 4E is a circuit diagram showing a binarization circuit according to the first embodiment, FIG. 4F is a circuit diagram showing a first comparator circuit, and FIG. 4G is a circuit diagram showing a second comparator circuit;

FIG. 5A is a graph showing an analog signal and comparison reference voltages, FIGS. 5B and 5C are graphs showing output voltages from comparator circuits, FIG. 5D is a graph showing a binarization signal obtained from the analog signal in FIG. 5A, FIG. 5E is a circuit diagram showing a binarization circuit according to a first modification of the first embodiment, FIG. 5F is a circuit diagram showing a first comparator circuit, and FIG. 5G is a circuit diagram showing a second comparator circuit;

FIG. 6A is a graph showing an analog signal and comparison reference voltages, FIGS. 6B and 6C are graphs showing output voltages from comparator circuits, FIG. 6D is a graph showing a binarization signal obtained from the analog signal in FIG. 6A, FIG. 6E is a circuit diagram showing a binarization circuit according to a second modification of the first embodiment, FIG. 6F is a circuit diagram showing a first comparator circuit, and FIG. 6G is a circuit diagram showing a second comparator circuit;

FIG. 7A is a graph showing an analog signal and comparison reference voltages, FIGS. 7B and 7C are graphs showing output voltages from comparator circuits, FIG. 7D is a graph showing a binarization signal obtained from the analog signal in FIG. 7A, FIG. 7E is a circuit diagram showing a binarization circuit according to a third modification of the first embodiment, FIG. 7F is a circuit diagram showing a first comparator circuit, and FIG. 7G is a circuit diagram showing a second comparator circuit;

FIG. 8 is a block diagram explaining a binarization method according to a second embodiment;

FIGS. 9A and 9B are circuit diagrams showing a binarization circuit according to the second embodiment;

FIGS. 10A to 10H are circuit diagrams showing various first and second comparator circuits according to modifications of the first embodiment;

FIG. 11 is a circuit diagram showing a binarization circuit according to a third embodiment;

FIG. 12 is a circuit diagram showing a concrete example of the binarization circuit in FIG. 11; and

FIG. 13A is a graph showing an analog signal and comparison reference voltages, FIGS. 13B and 13C are graphs showing output voltages from comparator circuits, and FIG. 13D is a graph showing a binarization signal obtained from the analog signal in FIG. 13A.

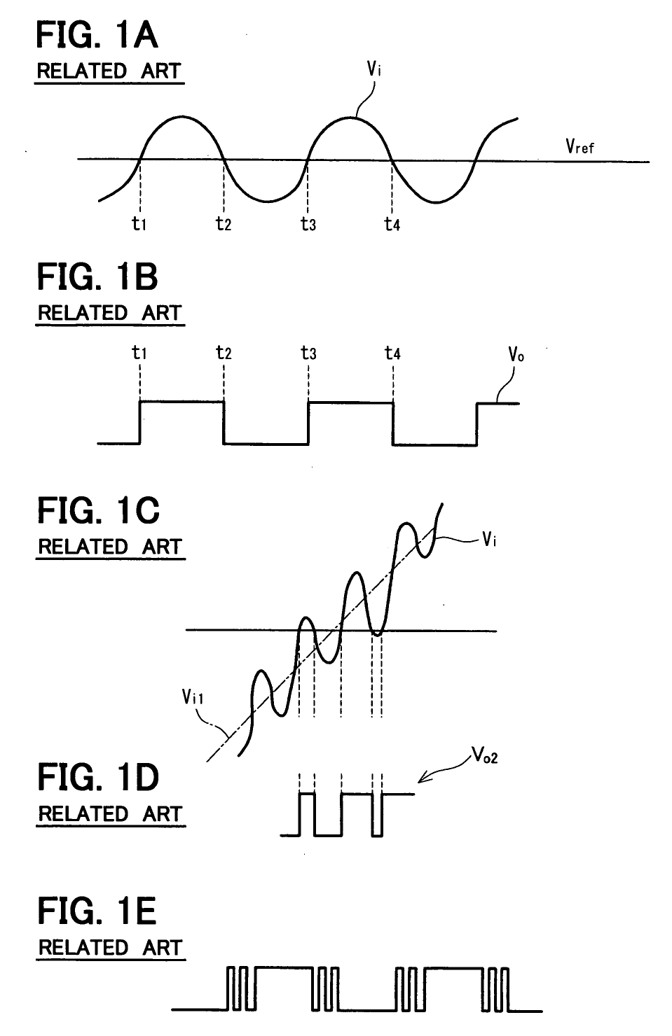

### DETAILED DESCRIPTION OF THE PREFERRED EMBODIMENTS

### First Embodiment

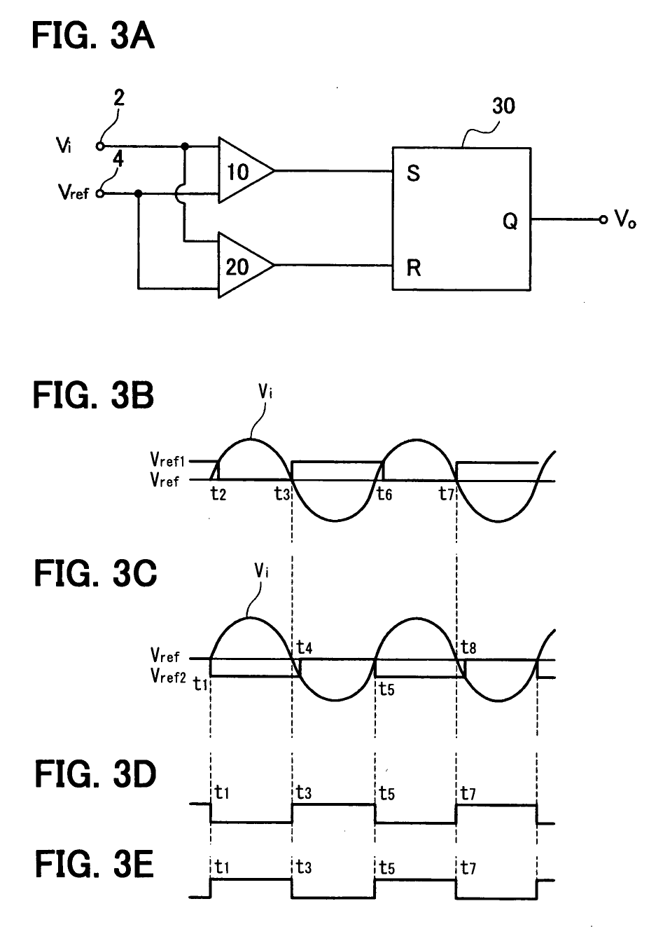

FIG. 3A shows a binarization circuit, which includes a first input terminal 2 for inputting a pulsative analog signal Vi, a second input terminal 4 for inputting a threshold voltage Vref, a first comparator circuit 10, a second comparator circuit 20 and a selector circuit 30 for outputting a binarization signal Vo.

The first comparator circuit 10 is a comparator having a predetermined hysteresis characteristic. As shown in FIG. 3B, when the analog signal Vi becomes larger than a high side offset threshold voltage Vref1 at a time t2, t6, a comparison reference voltage is switched to the threshold voltage Vref. When the analog signal Vi becomes smaller than the threshold voltage Vref at a time t3, t7, the comparison reference voltage is switched to the high side offset threshold voltage Vref1. The high side offset threshold voltage Vref1 is set to be higher than the threshold voltage Vref. Since the first comparator circuit 10 switches the comparison reference voltage, the output voltage of the first comparator circuit 10 does not chatter even when a high frequency component is overlapped on the analog signal Vi. The output voltage of the first comparator circuit 10 flips (or is reversed) when the analog signal Vi becomes larger than the high side offset threshold voltage Vref1 at the time t2, t6. Further, the output voltage of the first comparator circuit 10 flips again (or is reversed again) when the analog signal Vi becomes smaller than the threshold voltage Vref at the time t3, t7.

The second comparator circuit 20 is a comparator having a predetermined hysteresis characteristic. As shown in FIG. 3C, when the analog signal Vi becomes larger than the threshold voltage Vref at a time t1, t5, the comparison reference voltage is switched to a low side offset threshold voltage Vref2. When the analog signal Vi becomes smaller than the low side offset threshold voltage Vref2 at a time t4, t8, the comparison reference voltage is switched to the threshold voltage Vref. The low side offset threshold voltage Vref1 is set to be smaller than the threshold voltage Vref. Since the second comparator circuit 20 switches the comparison reference voltage, the output voltage of the second comparator circuit 20 does not chatter even when a high frequency component is overlapped on the analog signal Vi. The output voltage of the second comparator circuit 20 flips (or is reversed) when the analog signal Vi becomes larger than the threshold voltage Vref at the time t1, t5. Further, the output voltage of the second comparator circuit 20 flips again (or is reversed again) when the analog signal Vi becomes smaller than the low side offset threshold voltage Vref2 at the time t4, t8.

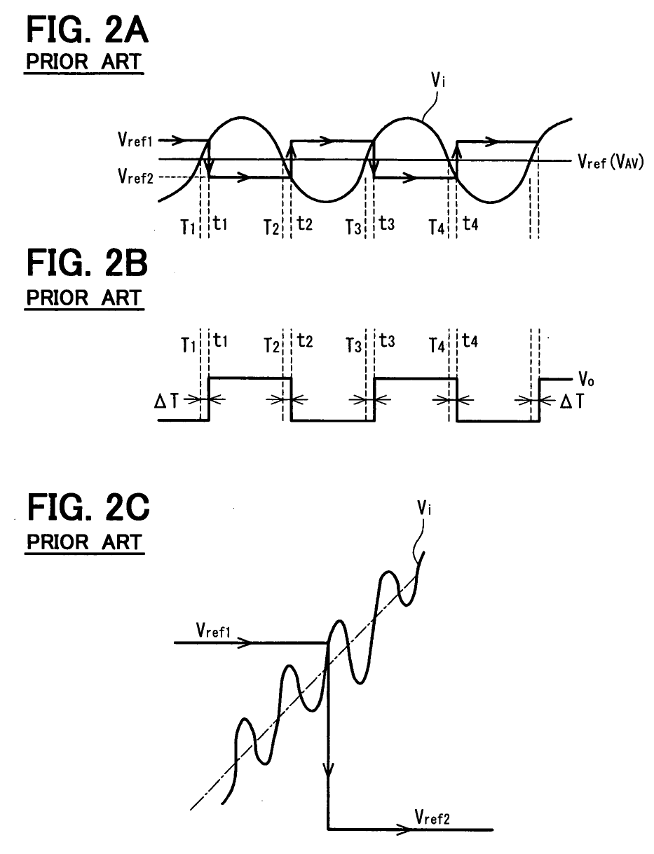

The selector circuit 30 inputs both of output voltages from the first and second comparator circuits 10, 20. When the analog signal Vi becomes larger than the high side offset threshold voltage Vref1 at the time t2, t6, the first comparator circuit 10 provides an output flip function. When the analog signal Vi becomes smaller than the threshold voltage Vref at the time t3, t7, the first comparator circuit 10 provides another output flip function. When the analog signal Vi becomes larger than the threshold voltage Vref at the time t1, t5, the second comparator circuit 20 provides an output flip function. When the analog signal Vi becomes smaller than the low side offset threshold voltage Vref2 at the time t4, t8, the second comparator circuit 20 provides another output flip function. Thus, the selector circuit 30 inputs the output flip functions of the first and second comparator circuits 10, 20 at the time t1-t8. The selector circuit 30 includes a flip-flop circuit having a set-reset function. The selector circuit 30 selects the output flip function of the first comparator circuit 10 at the time t3, t7 when the analog signal Vi becomes smaller than the threshold voltage Vref and the output flip function of the second comparator circuit 20 at the time t1, t5 when the analog signal Vi becomes larger than the threshold voltage Vref, so that the selector circuit 30 flips the output voltage Vo. FIG. 3D shows the output voltage Vo of the selector circuit 30. The output voltage Vo of the selector circuit 30 flips at the time t1, t3, t5, t7. Comparing the output voltage shown in FIG. 2B, the timing of flipping the output voltage Vo of the selector circuit 30 is not deviated from the time t1, t3, t5, t7. The timing of flipping and flipping again is important for the binarization signal. The output voltage Vo of the selector circuit 30 may be a graph shown in FIG. 3E. The graph of the binarization signal (i.e., the output voltage Vo) in FIG. 3D is opposite to the graph in FIG. 3E. Specifically, rising and falling of the binarization signal in FIG. 3D is opposite to those in FIG. 3E. The timing of flipping and flipping again in FIG. 3D coincides with that in FIG. 3E.

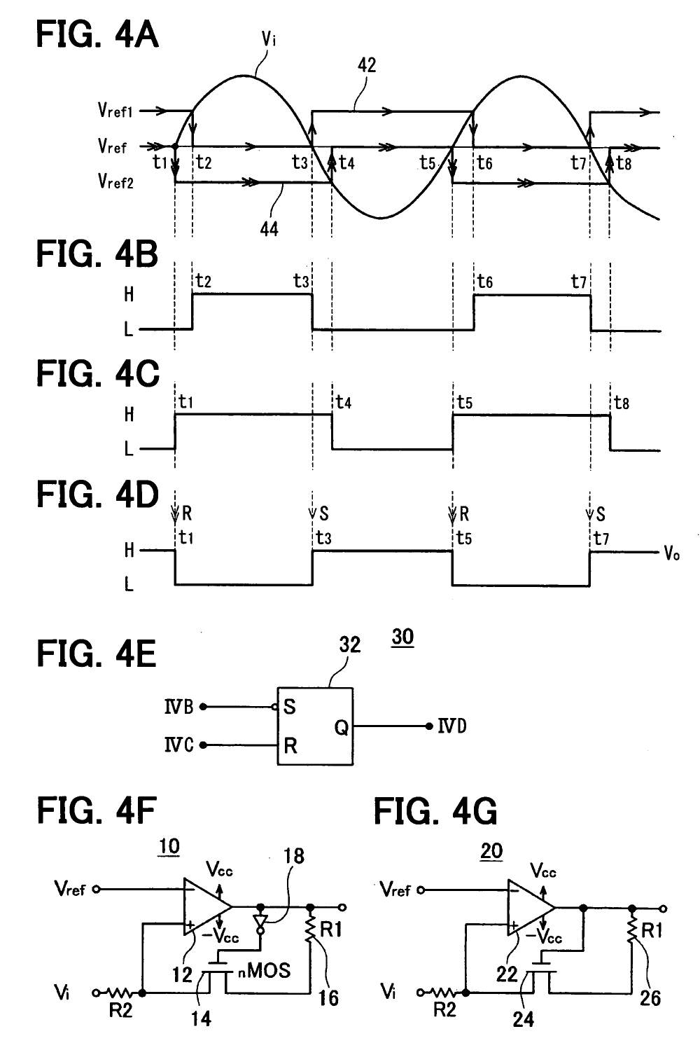

FIG. 4F shows the first comparator circuit 10. The first comparator circuit 10 includes a first comparator 12. The first comparator 12 has an output terminal and a non-inversion input terminal. A feedback resistor 16 and an N type MOS transistor 14 are connected in series between the output terminal and the non-inversion input terminal. An inverter 18 is formed between the gate of the N type MOS transistor 14 and the output terminal of the comparator 12. The threshold voltage Vref is inputted into the inversion input terminal of the first comparator 12. The analog signal Vi is inputted into the non-inversion input terminal of the first comparator 12 through a resistor R2. When the N type MOS transistor 14 is in a conduction state, a divided voltage between a resistor R1 and the resistor R2 is inputted into the non-inversion input terminal of the first comparator 12. When the N type MOS transistor 14 is in a non-conduction state, the analog signal Vi is inputted into the non-inversion input terminal of the first comparator 12. In this case, the analog signal Vi is offset so that the offset analog signal Vo is compared with the threshold voltage Vref. This operation corresponds that the threshold voltage Vref is offset so that the offset threshold voltage Vref is compared with the analog signal Vi. Here, the output voltage of the first comparator 12 flips so that the N type MOS transistor 14 switches between the conduction state and the non-conduction state. This switching of the N type MOS transistor 14 operates simultaneously with switching between an offset state and a non-offset state of the threshold voltage Vref in order to compare with the analog signal Vi.

When the first comparator circuit 10 functions, the comparison reference voltage is switched to the threshold voltage Vref when the analog signal Vi becomes larger than the high side offset threshold voltage Vref1 at the time t2, t6. Further, the comparison reference voltage is switched to the high side offset threshold voltage Vref1 when the analog signal Vi becomes smaller than the threshold voltage Vref at the time t3, t7. These are shown as a voltage level 42 in FIG. 4A, and the voltage level 42 changes step-wisely.

FIG. 4B shows the output voltage of the first comparator circuit 10. Specifically, the output voltage switches from a negative voltage (or a low state) to a positive voltage (or a high state) at the time t2, t6, and the output voltage switches from the positive voltage (or the high state) to the negative voltage (or the low state) at the time t3, t7.

FIG. 4G shows the second comparator circuit 20. The second comparator circuit 20 includes a second comparator 22. The second comparator 22 has an output terminal and a non-inversion input terminal. A feedback resistor 26 and an N type MOS transistor 24 are connected in series between the output terminal and the non-inversion input terminal. The gate of the N type MOS transistor 24 is connected to the output terminal of the comparator 22. No inverter is formed between the gate of the N type MOS transistor 24 and the output terminal of the comparator 22. The threshold voltage Vref is inputted into the inversion input terminal of the second comparator 22. The analog signal Vi is inputted into the non-inversion input terminal of the second comparator 22 through the resistor R2. In this circuit, the output voltage of the second comparator 22 flips, and the conduction state and the non-conduction state of the N type MOS transistor 24 are switched. An offset state and a non-offset state of the threshold voltage Vref to be compared with the analog signal Vi are switched.

When the second comparator circuit 20 functions, the comparison reference voltage is switched to the low side offset threshold voltage Vref2 when the analog signal Vi becomes larger than the threshold voltage Vref at the time t1, t5. Further, the comparison reference voltage is switched to the threshold voltage Vref when the analog signal Vi becomes smaller than the low side offset threshold voltage Vref2 at the time t4, t8. These are shown as a voltage level 44 in FIG. 4A, and the voltage level 44 changes step-wisely.

FIG. 4C shows the output voltage of the second comparator circuit 20. Specifically, the output voltage switches from a negative voltage (or a low state) to a positive voltage (or a high state) at the time t1, t5, and the output voltage switches from the positive voltage (or the high state) to the negative voltage (or the low state) at the time t4, t8.

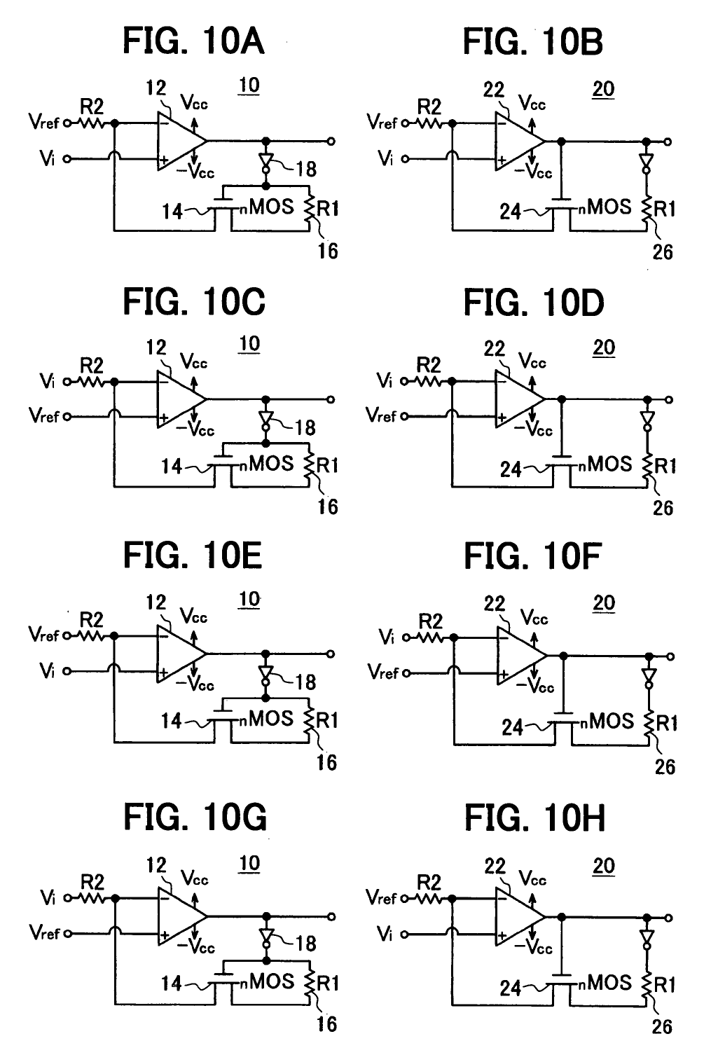

FIG. 10A shows another first comparator circuit 10, which functions equivalently to the first comparator circuit 10 shown in FIG. 4F. FIG. 10B shows another second comparator circuit 20, which functions equivalently to the second comparator circuit 20 shown in FIG. 4G.

FIG. 4E shows the selector circuit 30, which includes a flip-flop circuit 32 having a set terminal S and a reset terminal R. The flip-flop circuit 32 switches the output voltage Vo from a negative voltage to a positive voltage when the input voltage of the set terminal S switches from the negative voltage to the positive voltage. Further, the flip-flop circuit 32 switches the output voltage Vo from the positive voltage to the negative voltage when the input voltage of the reset terminal R switches from the negative voltage to the positive voltage.

Here, the output voltage (IVB) of the first comparator circuit 10 is reversed and inputted in the set terminal S. Thus, when the output voltage of the first comparator circuit 10 switches from the positive voltage to the negative voltage at the time t3, t7 in FIG. 4B, the input voltage of the set terminal S switches from the negative voltage to the positive voltage. At this time t3, t7, the flip-flop circuit 32 switches the output voltage Vo from the negative voltage to the positive voltage. Specifically, the output voltage (IVD) is outputted from the output terminal Q of the flip-flop circuit 32. The output voltage (IVC) of the second comparator circuit 20 is directly (i.e., not reversed) and inputted in the reset terminal R. Thus, when the output voltage of the second comparator circuit 20 switches from the negative voltage to the positive voltage at the time t1, t5 in FIG. 4C, the input voltage of the reset terminal R switches from the negative voltage to the positive voltage. At this time t1, t5, the flip-flop circuit 32 switches the output voltage Vo from the positive voltage to the negative voltage. Thus, the output voltage Vo of the binarization circuit provides the binarization signal Vo shown in FIG. 4D. The binarization signal Vo switches from the positive voltage to the negative voltage when the analog signal Vi becomes larger than the threshold voltage Vref at the time t1, t5, and the binarization signal Vo switches from the negative voltage to the positive voltage when the analog signal Vi becomes smaller than the threshold voltage Vref.

Alternatively, the output voltage of the first comparator circuit 10 may be directly inputted in the set terminal S, and the output voltage of the second comparator circuit 20 may be reversed and inputted in the reset terminal R. In this case, the flip-flop circuit 32 switches the output voltage Vo from the negative voltage to the positive voltage when the output voltage of the second comparator circuit 20 switches from the negative voltage to the positive voltage at the time t1, t5. Further, the flip-flop circuit 32 switches the output voltage Vo from the positive voltage to the negative voltage when the output voltage of the first comparator circuit 10 switches from the positive voltage to the negative voltage at the time t3, t7. Thus, the output voltage Vo of the binarization circuit provides the binarization signal Vo, which is opposite to the signal shown in FIG. 4D, and corresponds to the binarization signal shown in FIG. 3E.

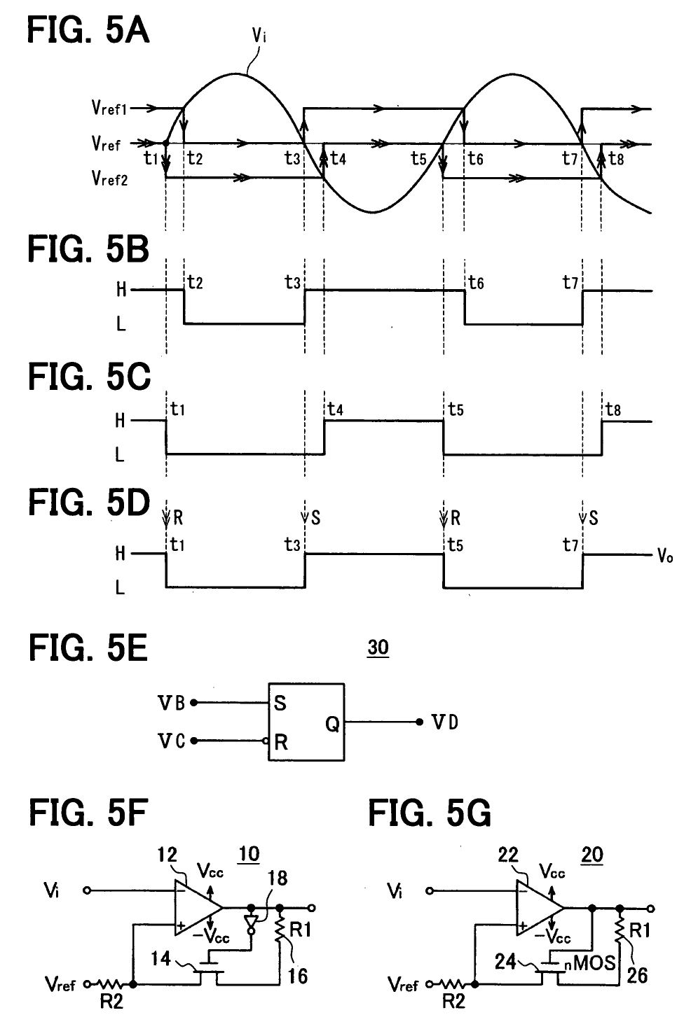

FIGS. 5A to 7G show various modifications of the bainarization circuit.

FIG. 5F shows another first comparator circuit 10. The analog signal Vi is inputted in the inversion input terminal of the comparator 12, and the threshold voltage Vref is inputted in the non-inversion input terminal of the comparator 12 through the resistor R2.

When the first comparator circuit 10 functions, the output voltage of the first comparator circuit 10 switches from the positive voltage to the negative voltage when the analog signal Vi becomes larger than the high side offset threshold voltage Vref1 at the time t2, t6, as shown in FIG. 5B. When the analog signal Vi becomes smaller than the threshold voltage Vref at the time t3, t7, the output voltage of the first comparator circuit 10 switches from the negative voltage to the positive voltage.

FIG. 5G shows another second comparator circuit 20. The analog signal Vi is inputted in the inversion input terminal of the comparator 22, and the threshold voltage Vref is inputted in the non-inversion input terminal of the comparator 22 through the resistor R2.

When the second comparator circuit 20 functions, the output voltage of the second comparator circuit 20 switches from the positive voltage to the negative voltage when the analog signal Vi becomes larger than the threshold voltage Vref at the time t1, t5, as shown in FIG. 5C. When the analog signal Vi becomes smaller than the low side offset threshold voltage Vref2 at the time t4, t8, the output voltage of the second comparator circuit 20 switches from the negative voltage to the positive voltage.

FIG. 10C shows another first comparator circuit 10, which functions equivalently to the first comparator circuit 10 shown in FIG. 5F. FIG. 10D shows another second comparator circuit 20, which functions equivalently to the second comparator circuit 20 shown in FIG. 5G.

FIG. 5E shows another selector circuit 30. The output voltage of the first comparator circuit 10 is inputted in the set terminal S without being reversed. The output voltage of the second comparator circuit 20 is inputted in the reset terminal R with being reversed. The flip-flop circuit 32 switches the output voltage Vo from the positive voltage to the negative voltage when the analog signal Vi becomes larger than the threshold voltage Vref at the time t1, t5. When the analog signal Vi becomes smaller than the threshold voltage Vref at the time t3, t5, the output voltage Vo switches from the negative voltage to the positive voltage. Thus, the output voltage Vo of the flip-flop circuit 32 provides the binarization signal Vo shown in FIG. 5D.

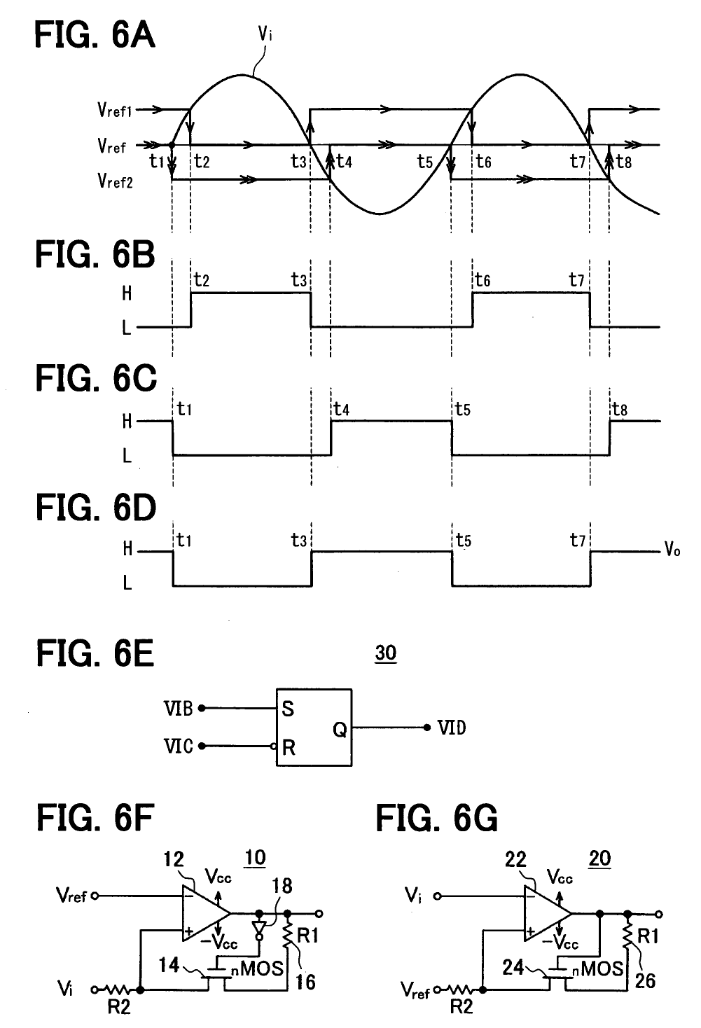

FIG. 6F shows further another first comparator circuit 10. The threshold voltage Vref is inputted in the inversion input terminal of the comparator 12, and the analog signal Vi is inputted in the non-inversion input terminal of the comparator 12 through the resistor R2.

When the first comparator circuit 10 functions, the output voltage of the first comparator circuit 10 switches from the negative voltage to the positive voltage when the analog signal Vi becomes larger than the high side offset threshold voltage Vref1 at the time t2, t6, as shown in FIG. 6B. When the analog signal Vi becomes smaller than the threshold voltage Vref at the time t3, t7, the output voltage of the first comparator circuit 10 switches from the positive voltage to the negative voltage.

FIG. 6G shows further another second comparator circuit 20. The analog signal Vi is inputted in the inversion input terminal of the comparator 22, and the threshold voltage Vref is inputted in the non-inversion input terminal of the comparator 22 through the resistor R2.

When the second comparator circuit 20 functions, the output voltage of the second comparator circuit 20 switches from the positive voltage to the negative voltage when the analog signal Vi becomes larger than the threshold voltage Vref at the time t1, t5, as shown in FIG. 6C. When the analog signal Vi becomes smaller than the low side offset threshold voltage Vref2 at the time t4, t8, the output voltage of the second comparator circuit 20 switches from the negative voltage to the positive voltage.

FIG. 10E shows another first comparator circuit 10, which functions equivalently to the first comparator circuit 10 shown in FIG. 6F. FIG. 10F shows another second comparator circuit 20, which functions equivalently to the second comparator circuit 20 shown in FIG. 6G.

FIG. 6E shows further another selector circuit 30. The output voltage of the first comparator circuit 10 is inputted in the set terminal S with being reversed. The output voltage of the second comparator circuit 20 is inputted in the reset terminal R with being reversed. The flip-flop circuit 32 switches the output voltage Vo from the positive voltage to the negative voltage when the analog signal Vi becomes larger than the threshold voltage Vref at the time t1, t5. When the analog signal Vi becomes smaller than the threshold voltage Vref at the time t3, t5, the output voltage Vo switches from the negative voltage to the positive voltage. Thus, the output voltage Vo of the flip-flop circuit 32 provides the binarization signal Vo shown in FIG. 6D.

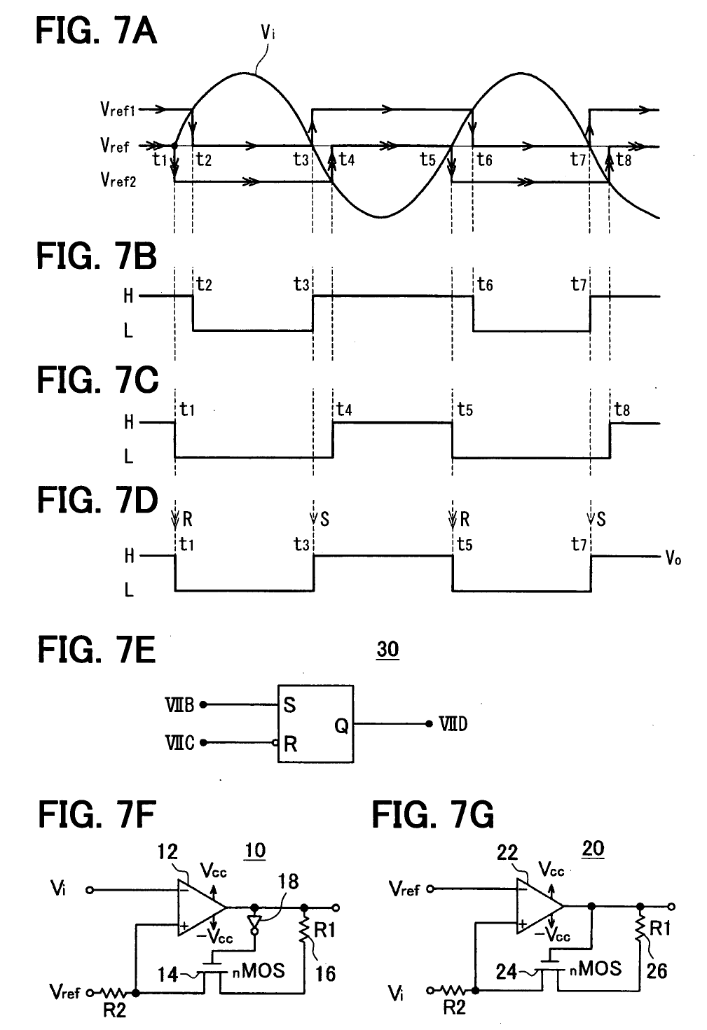

FIG. 7F shows another first comparator circuit 10. The analog signal Vi is inputted in the inversion input terminal of the comparator 12, and the threshold voltage Vref is inputted in the non-inversion input terminal of the comparator 12 through the resistor R2.

When the first comparator circuit 10 functions, the output voltage of the first comparator circuit 10 switches from the positive voltage to the negative voltage when the analog signal Vi becomes larger than the high side of set threshold voltage Vref1 at the time t2, t6, as shown in FIG. 7B. When the analog signal Vi becomes smaller than the threshold voltage Vref at the time t3, t7, the output voltage of the first comparator circuit 10 switches from the negative voltage to the positive voltage.

FIG. 7G shows another second comparator circuit 20. The analog signal Vi is inputted in the inversion input terminal of the comparator 22, and the threshold voltage Vref is inputted in the non-inversion input terminal of the comparator 22 through the resistor R2.

When the second comparator circuit 20 functions, the output voltage of the second comparator circuit 20 switches from the negative voltage to the positive voltage when the analog signal Vi becomes larger than the threshold voltage Vref at the time t1, t5, as shown in FIG. 7C. When the analog signal Vi becomes smaller than the low side offset threshold voltage Vref2 at the time t4, t8, the output voltage of the second comparator circuit 20 switches from the positive voltage to the negative voltage.

FIG. 10G shows another first comparator circuit 10, which functions equivalently to the first comparator circuit 10 shown in FIG. 7F. FIG. 10H shows another second comparator circuit 20, which functions equivalently to the second comparator circuit 20 shown in FIG. 7G.

FIG. 7E shows another selector circuit 30. The output voltage of the first comparator circuit 10 is inputted in the set terminal S without being reversed. The output voltage of the second comparator circuit 20 is inputted in the reset terminal R without being reversed. The flip-flop circuit 32 switches the output voltage Vo from the positive voltage to the negative voltage when the analog signal Vi becomes larger than the threshold voltage Vref at the time t1, t5. When the analog signal Vi becomes smaller than the threshold voltage Vref at the time t3, t5, the output voltage Vo switches from the negative voltage to the positive voltage. Thus, the output voltage Vo of the flip-flop circuit 32 provides the binarization signal Vo shown in FIG. 7D.

Although the first and second comparator circuits in FIGS. 4F-7F, 4G-7G and 10A-10H include the N type MOS transistors 14, 24, respectively, the first and second comparator circuits may include P type MOS transistors, respectively. In this case, in the first comparator circuit 10 shown in FIGS. 4F-7F, the output voltage of the comparator 12 is inputted in the gate of the P type MOS transistor without being reversed, and, in the second comparator circuit 20 shown in FIGS. 4G-7G, the output voltage of the comparator 12 is inputted in the gate of the P type MOS transistor with being reversed.

### Second Embodiment

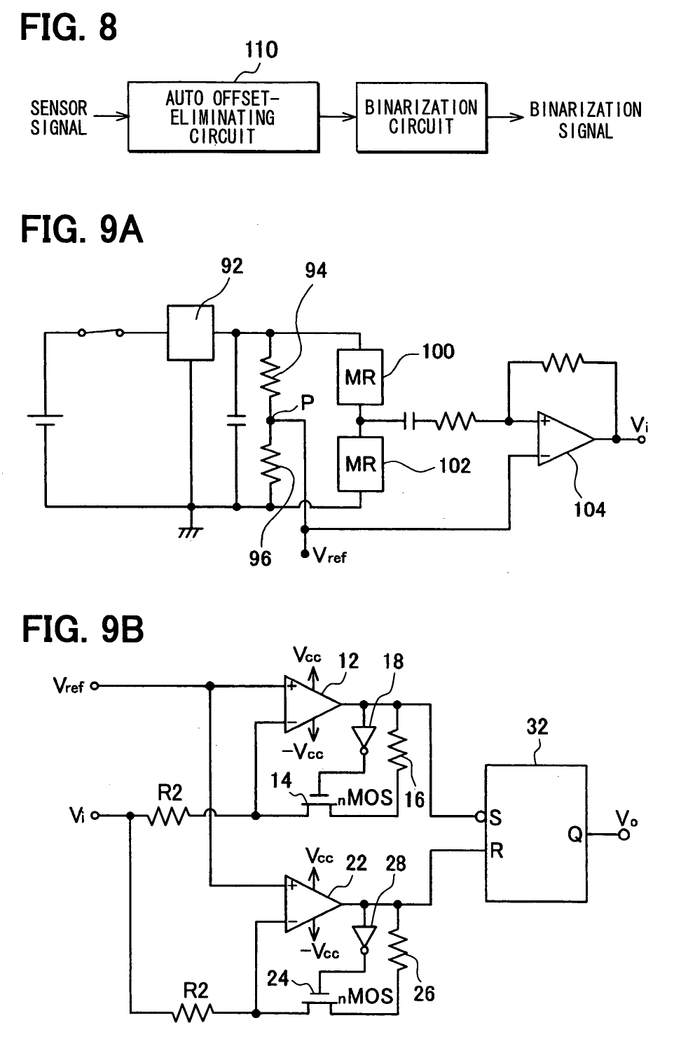

FIG. 8 shows a circuit 110 for aligning the threshold voltage Vref to an average voltage of the analog voltage Vi. In this case, the time interval between the time at which the output voltage of the binarization circuit switches from the positive voltage to the negative voltage and the time at which the output voltage of the bonarization circuit switches from the negative voltage to the positive voltage is substantially equal to the time interval between the time at which the output voltage switches from the negative voltage to the positive voltage and the time at which the output voltage switches from the positive voltage to the negative voltage.

FIGS. 9A and 9B show a circuit for obtaining an analog signal as a sensor signal from magneto resistance devices 100, 102. A voltage at point P is inputted in the inversion input terminal of a comparator 104. The voltage at the point P is provided by dividing with using the resistors 94, 96. The circuit shown in FIG. 9A includes an IC 92 for adjusting a predetermined constant voltage.

In general, the output voltage from the magneto resistance elements 100, 102 includes a bias voltage having a direct current component and an alternating current component. The alternating current component is overlapped on the bias voltage, and varies in a sine wave manner. The direct current component varies with temperature. The voltage at the point P defines the bias voltage of the analog signal Vi (i.e., the average voltage of the analog signal).

The voltage at the point P provides the threshold voltage Vref so that the binarization signal is obtained by using the average voltage of the analog signal Vi. In this case, the binarization signal has the time interval of the negative voltage equal to the time interval of the positive voltage. The time interval of the negative voltage is disposed between the time at which the output voltage Vo switches from the positive voltage to the negative voltage and the time at which the output voltage switches from the negative voltage to the positive voltage. The time interval of the positive voltage is disposed between the time at which the output voltage Vo switches from the negative voltage to the positive voltage and the time at which the output voltage switches from the positive voltage to the negative voltage.

### Third embodiment

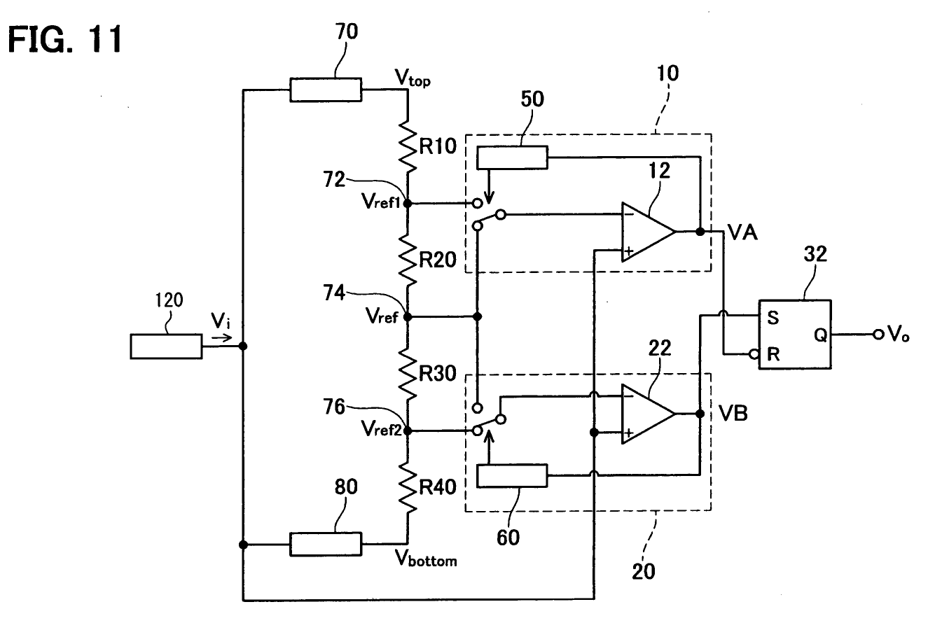

FIG. 11 shows a binarization circuit according to a third embodiment. The binarization circuit includes a peak hold circuit 70 and a bottom hold circuit 80. The peak hold circuit 70 maintains the peak voltage Vtop of the analog signal Vi, and the bottom hold circuit 80 maintains the bottom voltage Vbottom of the analog signal Vi. By using the top voltage Vtop and the bottom voltage Vbottom, the threshold voltage Vref, the high side offset threshold voltage Vref1 and the low side offset threshold voltage Vref2 are generated.

The analog signal Vi is inputted from a circuit 120 in each input terminal of the peak hold circuit 70 and the bottom hold circuit 80. Four resistors R10-R40 are connected in series between the output terminals of the peak hold circuit 70 and the bottom hold circuit 80. A first connection terminal 72 is formed between the resistors R10, R20, a second connection terminal 74 is formed between the resistors R20, R30, and a third connection terminal 76 is formed between the resistors R30, R40.

The resistances of the resistors R10-R40 are the same. Accordingly, the voltage at each connection terminal 72, 74, 76 is adjusted as follows.
Vref=(Vtop−Vbottom)×(½)+Vbottom (F1)
Vref1=(Vtop−Vbottom)×(¾)+Vbottom (F2)
Vref2=(Vtop−Vbottom)×(¼)+Vbottom (F3)

Here, the voltage at the connection terminal 72 is defined as Vref1, the voltage at the connection terminal 74 is defined as Vref, and the voltage at the connection terminal 76 is defined as Vref2.

The voltage Vref at the second connection terminal 74 is adjusted between the peak voltage Vtop and the bottom voltage Vbottom so that the voltage Vref provides the threshold voltage Vref. The voltage Vref1 at the first connection terminal 72 is adjusted between the threshold voltage Vref and the peak voltage Vtop so that the voltage Vref1 provides the high side offset threshold voltage Vref1. The voltage Vref2 at the third connection terminal 76 is adjusted between the threshold voltage Vref and the bottom voltage Vbottom so that the voltage Vref2 provides the low side offset threshold voltage Vref2.

As shown in FIG. 11, the first comparator circuit 10 includes a first comparator 12 and a first switching circuit 50. The analog signal Vi is inputted in the non-inversion input terminal of the first comparator 12. The first switching circuit 50 switches a connection between the inversion input terminal of the first comparator 12 and the first connection terminal 72 and a connection between the inversion input terminal and the second connection terminal 74 in accordance with the output voltage of the first comparator 12. Thus, the first switching circuit 50 switches an input voltage to the inversion input terminal of the first comparator 12 between the high side offset threshold voltage Vref1 and the threshold voltage Vref in accordance with the output voltage of the first comparator 12.

The second comparator circuit 20 includes a second comparator 22 and a second switching circuit 60. The analog signal Vi is inputted in the non-inversion input terminal of the second comparator 22. The second switching circuit 60 switches a connection between the inversion input terminal of the second comparator 22 and the second connection terminal 74 and a connection between the inversion input terminal and the third connection terminal 76 in accordance with the output voltage of the second comparator 22. Thus, the second switching circuit 60 switches an input voltage to the inversion input terminal of the second comparator 22 between the threshold voltage Vref and the low side offset threshold voltage Vref2 in accordance with the output voltage of the second comparator 22.

The binarization circuit further includes a flip-flop circuit 32 having a set-reset function. The output voltage of the first comparator 12 is reversed and inputted in the reset terminal R of the flip-flop circuit 32. The output voltage of the second comparator 12 is not reversed and inputted in the set terminal S of the flip-flop circuit 32.

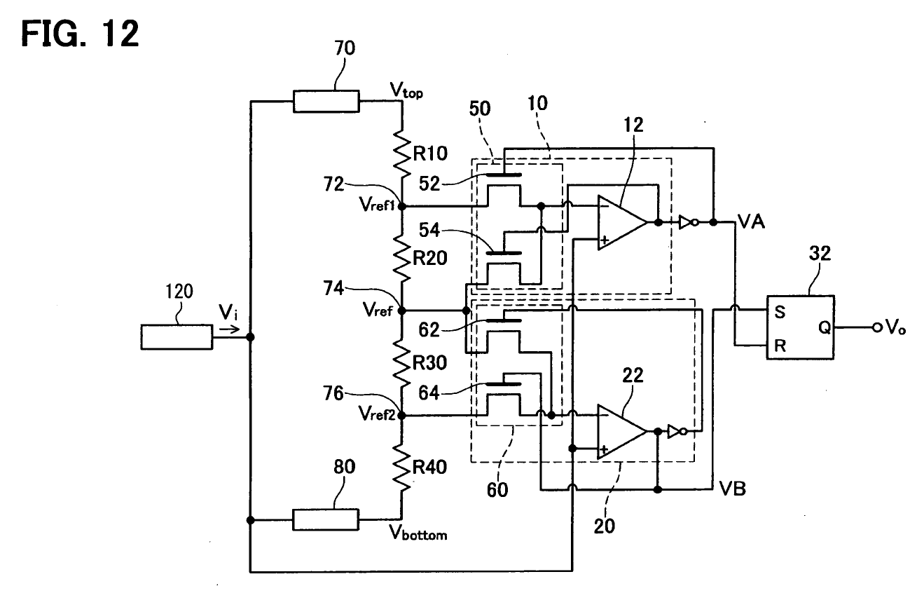

FIG. 12 shows a concrete example of the first and second switches 50, 60.

The first switching circuit 50 includes first and second transistors 52, 54. The first transistor 52 is formed between the inversion input terminal of the first comparator 12 and the first connection terminal 72. The output voltage of the first comparator 12 is reversed by an inverter, and then, the reversed output voltage is inputted in the gate of the first transistor 52. The second transistor 54 is formed between the inversion input terminal of the first comparator 12 and the second connection terminal 74. The output voltage of the first comparator 12 is not reversed by an inverter, so that the output voltage is directly inputted in the gate of the second transistor 54.

The second switching circuit 60 includes third and fourth transistors 62, 64.

The third transistor 62 is formed between the inversion input terminal of the second comparator 22 and the second connection terminal 74. The output voltage of the second comparator 22 is reversed by an inverter, and then, the reversed output voltage is inputted in the gate of the third transistor 62. The fourth transistor 64 is formed between the inversion input terminal of the second comparator 22 and the third connection terminal 76. The output voltage of the second comparator 22 is not reversed by an inverter, so that the output voltage is directly inputted in the gate of the fourth transistor 64.

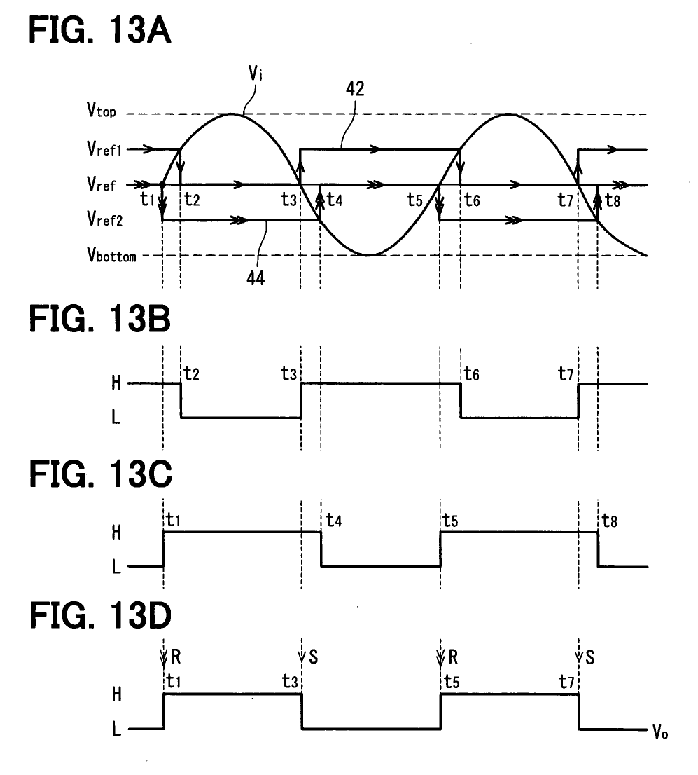

When the first comparator circuit 10 functions, the comparison reference voltage is switched to the threshold voltage Vref when the analog signal Vi becomes larger than the high side offset threshold voltage Vref1 at the time t2, t6. Further, the comparison reference voltage is switched to the high side offset threshold voltage Vref1 when the analog signal Vi becomes smaller than the threshold voltage Vref at the time t3, t7. These are shown as a voltage level 42 in FIG. 13A, and the voltage level 42 changes step-wisely.

FIG. 13B shows an output voltage VA after the output voltage of the first comparator circuit 10 is reversed by the inverter. Specifically, the output voltage VA is an input signal to the reset terminal R of the flip-flop circuit 32. The output voltage VA switches from a positive voltage to a negative voltage at the time t2, t6, and the output voltage VA switches from the negative voltage to the positive voltage at the time t3, t7.

When the second comparator circuit 20 functions, the comparison reference voltage is switched to the low side offset threshold voltage Vref2 when the analog signal Vi becomes larger than the threshold voltage Vref at the time t1, t5. Further, the comparison reference voltage is switched to the threshold voltage Vref when the analog signal Vi becomes smaller than the low side offset threshold voltage Vref2 at the time t4, t8. These are shown as a voltage level 44 in FIG. 13A, and the voltage level 44 changes step-wisely.

FIG. 13C shows the output voltage of the second comparator circuit 20. Specifically, the output voltage switches from a negative voltage to a positive voltage at the time t1, t5, and the output voltage switches from the positive voltage to the negative voltage at the time t4, t8.

Here, the output voltage of the first comparator circuit 10 is reversed and inputted in the reset terminal R of the flip-flop circuit 32. Thus, when the output voltage of the first comparator circuit 10 switches from the negative voltage to the positive voltage at the time t3, t7 in FIG. 13B, the output voltage Vo of the output terminal of the flip-flop circuit 32 switches from the positive voltage to the negative voltage. The output voltage of the second comparator circuit 20 shown in FIG. 13B is inputted in the set terminal S of the flip-flop circuit 32. When the output voltage of the second comparator circuit 20 switches from the negative voltage to the positive voltage at the time t1, t5 in FIG. 4C, the output voltage Vo of the output terminal of the flip-flop circuit 32 switches from the negative voltage to the positive voltage. Thus, the output voltage Vo of the binarization circuit provides the binarization signal Vo shown in FIG. 13D. The binarization signal Vo switches from the negative voltage to the positive voltage when the analog signal Vi becomes larger than the threshold voltage Vref at the time t1, t5, and the binarization signal Vo switches from the positive voltage to the negative voltage when the analog signal Vi becomes smaller than the threshold voltage Vref at the time t3, t7.

The binarization circuit generates the high side offset threshold voltage Vref1 and the low side offset threshold voltage vref2 by using the peak voltage Vtop and the bottom voltage Vbottom. The high side offset threshold Vref1 and the low side offset threshold Vref2 are variable according to an amplitude of the pulsative analog signal Vi.

For example, when the analog signal Vi is obtained from a magneto resistance element for measuring magnetic flux as a measurement object, the amplitude of the analog signal Vi is reduced in accordance with temperature change. For example, the amplitude of the analog signal from the magneto resistance element is reduced to one-fourth when an environmental temperature is changed from −40° C. to +180° C. Thus, if the high side offset threshold voltage Vref1 and the low side offset threshold voltage Vref2 are fixed to predetermined voltages, the reduced analog signal Vi may not become higher than the high and low side offset threshold voltages Vref1, Vref2 since the amplitude of the analog voltage Vi is too small. In this case, the analog signal is not binarized accurately. However, the binarization circuit shown in FIG. 11 can binarize the analog signal Vi accurately even when the amplitude of the analog signal Vi becomes small. This is because the high and low side offset threshold voltages Vref1, Vref2 are adjusted in accordance with the amplitude of the analog signal Vi.

The above disclosure has the following aspects.

According to an aspect of the present disclosure, a binarization circuit for binarizing a pulsative analog signal includes: a first comparator circuit for reversing an output signal thereof when the analog signal becomes smaller than a predetermined threshold voltage and when the analog signal becomes larger than a high side threshold voltage, wherein the high side threshold voltage is higher than the threshold voltage; a second comparator circuit for reversing an output signal thereof when the analog signal becomes larger than the threshold voltage and when the analog signal becomes smaller than a low side threshold voltage, wherein the low side threshold voltage is lower than the threshold voltage; and a selector circuit for inputting the output signals from the first and second comparator circuits and for reversing an output signal of the selector circuit. The output signal of the selector circuit is reversed when the first comparator circuit reverses the output signal of the first comparator circuit in a case where the analog signal becomes smaller than the threshold voltage and when the second comparator circuit reverses the output signal of the second comparator circuit in a case where the analog signal becomes larger than the threshold voltage.

In the above circuit, since each of the first and second comparator circuits has a hysteresis characteristic, the output of the circuit does not chatter when the analog signal becomes smaller than the threshold voltage and when the analog signal becomes larger than the threshold voltage. Further, the binarization signal is reversed when the analog signal becomes smaller than the threshold voltage and when the analog signal becomes larger than the threshold voltage.

Alternatively, the first comparator circuit may include a first input terminal for inputting the threshold voltage and a circuit for generating the high side threshold voltage based on the threshold voltage, and the second comparator circuit may include a first input terminal for inputting the threshold voltage and a circuit for generating the low side threshold voltage based on the threshold voltage. In this case, there in no need to input the high side threshold voltage and the low side threshold voltage in the first and second comparator circuits, respectively.

Further, the first comparator circuit may further include a second input terminal for inputting the analog signal, and the circuit of the first comparator circuit may include a comparator, a N type MOS transistor, an inverter and a first resistor. The first input terminal of the first comparator circuit is coupled with an inversion input terminal of the comparator. The second input terminal of the first comparator circuit is coupled with a non-inversion input terminal of the comparator through a second resistor. The inverter and the N type MOS transistor of the first comparator are coupled in series between an output terminal of the comparator and the non-inversion input terminal of the comparator. The first resistor of the first comparator is coupled between the output terminal of the comparator and the N type MOS transistor. The second comparator circuit may further include a second input terminal for inputting the analog signal, and the circuit of the second comparator circuit may include a comparator, a N type MOS transistor and a first resistor. The first input terminal of the second comparator circuit is coupled with an inversion input terminal of the comparator. The second input terminal of the second comparator circuit is coupled with a non-inversion input terminal of the comparator through a second resistor. The N type MOS transistor of the second comparator is coupled between an output terminal of the comparator and the non-inversion input terminal of the comparator. The first resistor of the second comparator is coupled between the output terminal of the comparator and the N type MOS transistor.

Furthermore, the selector circuit may include a flip-flop circuit having a set terminal and a reset terminal. The first comparator circuit is coupled with the set terminal of the selector circuit through an inversion input element, and the second comparator circuit is coupled with the reset terminal of the selector circuit.

Alternatively, the circuit may further include a circuit for outputting the analog signal. The first comparator circuit includes a first input terminal for inputting the threshold voltage and a second input terminal. The second comparator circuit includes a first input terminal for inputting the threshold voltage and a second input terminal. The circuit for outputting the analog signal has a terminal, at which an average voltage of the analog signal is provided. The second input terminal of each of the first and second comparator circuits is coupled with the terminal of the circuit for outputting the analog signal.

Further, the circuit of the first comparator circuit may include a comparator, a N type MOS transistor, an inverter and a first resistor. The first input terminal of the first comparator circuit is coupled with a non-inversion input terminal of the comparator. The second input terminal of the first comparator circuit is coupled with an inversion input terminal of the comparator. The inverter and the N type MOS transistor of the first comparator are coupled in series between an output terminal of the comparator and the inversion input terminal of the comparator. The first resistor of the first comparator is coupled between the output terminal of the comparator and the N type MOS transistor. The circuit of the second comparator circuit may include a comparator, a N type MOS transistor, an inverter and a first resistor. The first input terminal of the second comparator circuit is coupled with a non-inversion input terminal of the comparator. The second input terminal of the second comparator circuit is coupled with an inversion input terminal of the comparator. The inverter and the N type MOS transistor of the second comparator is coupled between an output terminal of the comparator and the inversion input terminal of the comparator. The first resistor of the second comparator is coupled between the output terminal of the comparator and the N type MOS transistor.

Furthermore, the selector circuit may include a flip-flop circuit having a set terminal and a reset terminal. The first comparator circuit is coupled with the set terminal of the selector circuit through an inversion input element, and the second comparator circuit is coupled with the reset terminal of the selector circuit.

Alternatively, the circuit may further include: a circuit for outputting the analog signal; a peak hold circuit for maintaining a peak voltage of the analog signal; and a bottom hold circuit for maintaining a bottom voltage of the analog signal. The peak hold circuit is coupled with the circuit for outputting the analog signal. The bottom hold circuit is coupled with the circuit for outputting the analog signal. The threshold is disposed between the peak voltage and the bottom voltage. In this case, even when the analog signal is increasing as a whole or even when the analog signal is decreasing as a whole, the analog signal is binarized accurately.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A binarization circuit for binarizing a pulsative analog signal comprising:
a first comparator circuit for reversing an output signal thereof when the analog signal becomes smaller than a predetermined threshold voltage and when the analog signal becomes larger than a high side threshold voltage, wherein the high side threshold voltage is higher than the threshold voltage;
a second comparator circuit for reversing an output signal thereof when the analog signal becomes larger than the threshold voltage and when the analog signal becomes smaller than a low side threshold voltage, wherein the low side threshold voltage is lower than the threshold voltage; and
a selector circuit for inputting the output signals from the first and second comparator circuits and for reversing an output signal of the selector circuit, wherein
the output signal of the selector circuit is reversed when the first comparator circuit reverses the output signal of the first comparator circuit in a case where the analog signal becomes smaller than the threshold voltage and when the second comparator circuit reverses the output signal of the second comparator circuit in a case where the analog signal becomes larger than the threshold voltage.

2. The circuit according to claim 1, wherein
the first comparator circuit includes a first input terminal for inputting the threshold voltage and a circuit for generating the high side threshold voltage based on the threshold voltage, and
the second comparator circuit includes a first input terminal for inputting the threshold voltage and a circuit for generating the low side threshold voltage based on the threshold voltage.

3. The circuit according to claim 2, wherein
the first comparator circuit further includes a second input terminal for inputting the analog signal,
the circuit of the first comparator circuit includes a comparator, a N type MOS transistor, an inverter and a first resistor,
the first input terminal of the first comparator circuit is coupled with an inversion input terminal of the comparator,
the second input terminal of the first comparator circuit is coupled with a non-inversion input terminal of the comparator through a second resistor,
the inverter and the N type MOS transistor of the first comparator circuit are coupled in series between an output terminal of the comparator and the non-inversion input terminal of the comparator,
the first resistor of the first comparator circuit is coupled between the output terminal of the comparator and the N type MOS transistor,
the second comparator circuit further includes a second input terminal for inputting the analog signal,
the circuit of the second comparator circuit includes a comparator, a N type MOS transistor and a first resistor,
the first input terminal of the second comparator circuit is coupled with an inversion input terminal of the comparator,
the second input terminal of the second comparator circuit is coupled with a non-inversion input terminal of the comparator through a second resistor,
the N type MOS transistor of the second comparator circuit is coupled between an output terminal of the comparator and the non-inversion input terminal of the comparator, and
the first resistor of the second comparator circuit is coupled between the output terminal of the comparator and the N type MOS transistor.

4. The circuit according to claim 3, wherein
the selector circuit includes a flip-flop circuit having a set terminal and a reset terminal,
the first comparator circuit is coupled with the set terminal of the selector circuit through an inversion input element, and
the second comparator circuit is coupled with the reset terminal of the selector circuit.

5. The circuit according to claim 2, wherein
the first comparator circuit further includes a second input terminal for inputting the analog signal,
the circuit of the first comparator circuit includes a comparator, a N type MOS transistor, an inverter and a first resistor,
the first input terminal of the first comparator circuit is coupled with a non-inversion input terminal of the comparator through a second resistor,
the second input terminal of the first comparator circuit is coupled with an inversion input terminal of the comparator,
the inverter and the N type MOS transistor of the first comparator circuit are coupled in series between an output terminal of the comparator and the non-inversion input terminal of the comparator,
the first resistor of the first comparator circuit is coupled between the output terminal of the comparator and the N type MOS transistor,
the second comparator circuit further includes a second input terminal for inputting the analog signal,
the circuit of the second comparator circuit includes a comparator, a N type MOS transistor and a first resistor,
the first input terminal of the second comparator circuit is coupled with a non-inversion input terminal of the comparator through a second resistor,
the second input terminal of the second comparator circuit is coupled with an inversion input terminal of the comparator,
the N type MOS transistor of the second comparator circuit is coupled between an output terminal of the comparator and the non-inversion input terminal of the comparator, and
the first resistor of the second comparator circuit is coupled between the output terminal of the comparator and the N type MOS transistor.

6. The circuit according to claim 5, wherein
the selector circuit includes a flip-flop circuit having a set terminal and a reset terminal,
the first comparator circuit is coupled with the set terminal of the selector circuit, and
the second comparator circuit is coupled with the reset terminal of the selector circuit through an inversion input element.

7. The circuit according to claim 2, wherein
the first comparator circuit further includes a second input terminal for inputting the analog signal,
the circuit of the first comparator circuit includes a comparator, a N type MOS transistor, an inverter and a first resistor,
the first input terminal of the first comparator circuit is coupled with an inversion input terminal of the comparator,
the second input terminal of the first comparator circuit is coupled with a non-inversion input terminal of the comparator through a second resistor,
the inverter and the N type MOS transistor of the first comparator circuit are coupled in series between an output terminal of the comparator and the non-inversion input terminal of the comparator,
the first resistor of the first comparator circuit is coupled between the output terminal of the comparator and the N type MOS transistor,
the second comparator circuit further includes a second input terminal for inputting the analog signal,
the circuit of the second comparator circuit includes a comparator, a N type MOS transistor and a first resistor,
the first input terminal of the second comparator circuit is coupled with a non-inversion input terminal of the comparator through a second resistor,
the second input terminal of the second comparator circuit is coupled with an inversion input terminal of the comparator,
the N type MOS transistor of the second comparator circuit is coupled between an output terminal of the comparator and the non-inversion input terminal of the comparator, and
the first resistor of the second comparator circuit is coupled between the output terminal of the comparator and the N type MOS transistor.

8. The circuit according to claim 7, wherein
the selector circuit includes a flip-flop circuit having a set terminal and a reset terminal,
the first comparator circuit is coupled with the set terminal of the selector circuit through an inversion input element, and
the second comparator circuit is coupled with the reset terminal of the selector circuit through an inversion input element.

9. The circuit according to claim 2, wherein
the first comparator circuit further includes a second input terminal for inputting the analog signal,
the circuit of the first comparator circuit includes a comparator, a N type MOS transistor, an inverter and a first resistor,
the first input terminal of the first comparator circuit is coupled with a non-inversion input terminal of the comparator through a second resistor,
the second input terminal of the first comparator circuit is coupled with an inversion input terminal of the comparator,
the inverter and the N type MOS transistor of the first comparator circuit are coupled in series between an output terminal of the comparator and the non-inversion input terminal of the comparator,
the first resistor of the first comparator circuit is coupled between the output terminal of the comparator and the N type MOS transistor,
the second comparator circuit further includes a second input terminal for inputting the analog signal,
the circuit of the second comparator circuit includes a comparator, a N type MOS transistor and a first resistor,
the first input terminal of the second comparator circuit is coupled with an inversion input terminal of the comparator,
the second input terminal of the second comparator circuit is coupled with a non-inversion input terminal of the comparator through a second resistor,
the N type MOS transistor of the second comparator circuit is coupled between an output terminal of the comparator and the non-inversion input terminal of the comparator, and
the first resistor of the second comparator circuit is coupled between the output terminal of the comparator and the N type MOS transistor.

10. The circuit according to claim 9, wherein
the selector circuit includes a flip-flop circuit having a set terminal and a reset terminal,
the first comparator circuit is coupled with the set terminal of the selector circuit, and
the second comparator circuit is coupled with the reset terminal of the selector circuit.

11. The circuit according to claim 1, further comprising:
a circuit for outputting the analog signal, wherein
the first comparator circuit includes a first input terminal for inputting the threshold voltage and a second input terminal,
the second comparator circuit includes a first input terminal for inputting the threshold voltage and a second input terminal,
the circuit for outputting the analog signal has a terminal, at which an average voltage of the analog signal is provided, and
the second input terminal of each of the first and second comparator circuits is coupled with the terminal of the circuit for outputting the analog signal.

12. The circuit according to claim 11, wherein
the circuit of the first comparator circuit includes a comparator, a N type MOS transistor, an inverter and a first resistor,
the first input terminal of the first comparator circuit is coupled with a non-inversion input terminal of the comparator,
the second input terminal of the first comparator circuit is coupled with an inversion input terminal of the comparator,
the inverter and the N type MOS transistor of the first comparator circuit are coupled in series between an output terminal of the comparator and the inversion input terminal of the comparator,
the first resistor of the first comparator circuit is coupled between the output terminal of the comparator and the N type MOS transistor,
the circuit of the second comparator circuit includes a comparator, a N type MOS transistor, an inverter and a first resistor,
the first input terminal of the second comparator circuit is coupled with a non-inversion input terminal of the comparator,
the second input terminal of the second comparator circuit is coupled with an inversion input terminal of the comparator,
the inverter and the N type MOS transistor of the second comparator circuit is coupled between an output terminal of the comparator and the inversion input terminal of the comparator, and
the first resistor of the second comparator circuit is coupled between the output terminal of the comparator and the N type MOS transistor.

13. The circuit according to claim 12, wherein
the selector circuit includes a flip-flop circuit having a set terminal and a reset terminal,
the first comparator circuit is coupled with the set terminal of the selector circuit through an inversion input element, and
the second comparator circuit is coupled with the reset terminal of the selector circuit.

14. The circuit according to claim 1, further comprising:
a circuit for outputting the analog signal;
a peak hold circuit for maintaining a peak voltage of the analog signal; and
a bottom hold circuit for maintaining a bottom voltage of the analog signal, wherein
the peak hold circuit is coupled with the circuit for outputting the analog signal,
the bottom hold circuit is coupled with the circuit for outputting the analog signal, and
the threshold voltage is disposed between the peak voltage and the bottom voltage.

15. The circuit according to claim 14, wherein
the threshold voltage is disposed at a center voltage between the peak voltage and the bottom voltage.

16. The circuit according to claim 14, wherein
the high side threshold voltage is disposed between the peak voltage and the threshold voltage, and
the low side threshold voltage is disposed between the threshold voltage and the bottom voltage.
